(19) United States
(12) Patent Application Publication
(10) Pub. No.: US 2021/0134567 A1
(43) Pub. Date: May 6, 2021

(54) SUBSTRATE TREATING APPARATUS

(71) Applicant: PSK INC., Gyeonggi-do (KR)

(72) Inventors: Kwang Sung Yoo, Gyeonggi-do (KR); Jung Hyun Kang, Gyeonggi-do (KR); Seong Hun Kang, Gyeonggi-do (KR)

(21) Appl. No.: 16/701,197

(22) Filed: Dec. 3, 2019

(30) Foreign Application Priority Data
Nov. 5, 2019 (KR) 10-2019-0140340

(51) Int. Cl. H01J 37/32

(52) U.S. Cl. CPC H01J 37/32834; H01J 37/32724

(57) ABSTRACT

An apparatus for treating a substrate includes a housing having a process space inside and having an exhaust hole formed through the housing, a support unit that supports the substrate in the process space, and an exhaust unit that is provided at the bottom of the housing and that exhausts the process space. The exhaust unit includes a body having a buffer space inside and having a through-hole formed through the body, the buffer space connecting to the process space, and an exhaust pipe that discharges gas in the buffer space. The support unit includes a support plate that supports the substrate in the process space and a support shaft connected with the support plate and inserted into the through-hole and the exhaust hole, the support shaft having a smaller diameter than the through-hole.

### CROSS-REFERENCE TO RELATED APPLICATIONS

A claim for priority under 35 U.S.C. § 119 is made to Korean Patent Application No. 10-2019-0140340 filed on Nov. 5, 2019, in the Korean Intellectual Property Office, the entire contents of which are hereby incorporated by reference.

### BACKGROUND

Embodiments of the inventive concept described herein relate to a substrate treating apparatus, and more particularly, relate to a substrate treating apparatus for treating a substrate using plasma.

Plasma refers to an ionized gaseous state of matter containing ions, radicals, and electrons and is generated by heating a neutral gas to a very high temperature or subjecting a neutral gas to a strong electric field or an RF electromagnetic field. Semiconductor device manufacturing processes include an ashing or etching process of removing a thin film on a substrate by using plasma. The ashing or etching process is performed by allowing ions and radicals contained in the plasma to collide or react with the film on the substrate.

FIG. 1 is a view illustrating a general plasma processing apparatus. Referring to FIG. 1, the plasma processing apparatus 2000 includes a process unit 2100 and a plasma generation unit 2300.

The process unit 2100 treats a substrate W by using plasma generated by the plasma generation unit 2300. The process unit 2100 includes a housing 2110, a support unit 2120, and a baffle 2130. The housing 2110 has an interior space 2112, and the support unit 2120 supports the substrate W in the interior space 2112. The baffle 2130 has a plurality of holes formed therein and is disposed over the support unit 2120.

The plasma generation unit 2300 generates plasma. The plasma generation unit 2300 includes a plasma generation chamber 2310, a gas supply unit 2320, a power supply unit 2330, and a diffusion chamber 2340. A process gas supplied by the gas supply unit 2320 is excited into a plasma state by RF power applied by the power supply unit 2330. The generated plasma is supplied into the interior space 2112 through the diffusion chamber 2340.

The plasma P and the process gas supplied into the interior space 2112 is delivered to the substrate W to treat the substrate W. Thereafter, the plasma P and/or the process gas is discharged to the outside through exhaust ports 2114 connected with the housing 2110. In the general substrate treating apparatus 2000, the exhaust ports 2114 are connected to the edge region of the housing 2110. This is because a support shaft included in the support unit 2120 is disposed in the central region of the interior space 2112. In the case where the exhaust ports 2114 are connected with the edge region of the housing 2110, the plasma P and/or the process gas in the interior space 2112 flows toward the edge region of the interior space 2112. In this case, the plasma P may not be appropriately delivered to the substrate W, and therefore the efficiency in treating the substrate W may be deteriorated. Accordingly, a way of locating the exhaust ports 2114 at close positions to the support shaft may be taken into consideration. However, in this case, the plasma P and/or the process gas may be asymmetrically discharged. Therefore, the uniformity of substrate treatment may be deteriorated. Furthermore, in the case where the exhaust ports 2114 are disposed in the central region of the housing 2110, there may be a space limitation due to the interference between the exhaust ports 2114 and the support shaft of the support unit 2120.

### SUMMARY

Embodiments of the inventive concept provide a substrate treating apparatus for efficiently treating a substrate.

Furthermore, embodiments of the inventive concept provide a substrate treating apparatus for uniformly performing substrate treatment by allowing plasma and/or gas to uniformly flow in the interior space of a housing.

In addition, embodiments of the inventive concept provide a substrate treating apparatus for minimizing a space limitation in the arrangement of an exhaust pipe due to a support shaft.

The technical problems to be solved by the inventive concept are not limited to the aforementioned problems, and any other technical problems not mentioned herein will be clearly understood from this specification and the accompanying drawings by those skilled in the art to which the inventive concept pertains.

According to an exemplary embodiment, an apparatus for treating a substrate includes a housing having a process space inside and having an exhaust hole formed through the housing, a support unit that supports the substrate in the process space, and an exhaust unit that is provided at the bottom of the housing and that exhausts the process space. The exhaust unit includes a body having a buffer space inside and having a through-hole formed through the body, the buffer space connecting to the process space, and an exhaust pipe that discharges gas in the buffer space. The support unit includes a support plate that supports the substrate in the process space and a support shaft connected with the support plate and inserted into the through-hole and the exhaust hole, the support shaft having a smaller diameter than the through-hole.

According to an embodiment, the exhaust unit may further include a perforated plate provided in the buffer space and having a plurality of perforations formed through the perforated plate, and the perforated plate may surround the support shaft and may be spaced apart from the support shaft.

According to an embodiment, the exhaust pipe may be connected to an edge of the buffer space when viewed from above.

According to an embodiment, the body may include an insertion part having a ring shape through which the through-hole is formed and a discharge part extending from the insertion part in a direction away from the support shaft. The exhaust pipe may be connected to the discharge part.

According to an embodiment, a blocking plate may be provided at the top of the body.

According to an embodiment, the body may be combined with the housing to form the buffer space.

According to an embodiment, the center of the support shaft and the center of the through-hole may coincide with each other when viewed from above.

According to an embodiment, the support shaft may be provided so as to be movable in an up/down direction, and the apparatus may further include a bellows that surrounds the support shaft and that is coupled with the body.

According to an embodiment, the apparatus may further include a gas supply unit that is located over the support unit and that supplies the gas into the process space.

According to an embodiment, the apparatus may further include a power supply unit that is located over the support unit and that generates plasma from the gas.

According to an embodiment, the support plate may have a circular plate shape, and a side of the support plate may be spaced apart from an inner wall of the housing.

According to an embodiment, the exhaust hole may be formed in the center of the bottom of the housing.

According to an embodiment, the support plate may be connected with a power source and may generate electrostatic force, and an interface line connecting the power source and the support plate may be provided in the support shaft.

According to an embodiment, a temperature adjustment member that adjusts temperature of the support plate may be provided in the support plate, and an interface line connecting the temperature adjustment member and a power source may be provided in the support shaft.

According to an embodiment, a lower electrode may be provided in the support plate, the lower electrode may be connected with an RF power source that supplies RF power to the lower electrode, and a power line connecting the lower electrode and the RF power source may be provided in the support shaft.

According to an exemplary embodiment, an apparatus for treating a substrate includes an equipment front end module having a load port on which a carrier having the substrate received therein is seated and a process module that treats the substrate transferred from the equipment front end module. The process module includes a transfer chamber that transfers the substrate and a process chamber that is disposed adjacent to the transfer chamber and that treats the substrate. The process chamber includes a housing having a process space inside and having an exhaust hole formed through the housing, a support unit that supports the substrate in the process space, a gas supply unit that is located over the support unit and that supplies gas into the process space, a plasma generation unit that is located over the support unit and that generates plasma from the gas, and an exhaust unit that is provided at the bottom of the housing and that exhausts the process space. The exhaust unit includes a body having a buffer space inside and having a through-hole formed through the body, the buffer space connecting to the process space, and an exhaust pipe that discharges the gas in the buffer space. The support unit includes a support plate that supports the substrate in the process space and a support shaft connected with the support plate and inserted into the through-hole and the exhaust hole, the support shaft having a smaller diameter than the through-hole.

According to an embodiment, the exhaust unit may further include a perforated plate provided in the buffer space and having a plurality of perforations formed through the perforated plate, and the perforated plate may surround the support shaft and may be spaced apart from the support shaft.

According to an embodiment, the body may include an insertion part having a ring shape through which the through-hole is formed and a discharge part extending from the insertion part in a direction away from the support shaft. The exhaust pipe may be connected to the discharge part.

According to an exemplary embodiment, an apparatus for treating a substrate includes a housing having a process space inside and having an exhaust hole formed through the housing and an exhaust unit that exhausts the process space. The exhaust unit includes a body having a buffer space inside and having a through-hole formed through the body and an exhaust pipe connected with the buffer space. Gas in the process space passes through the exhaust hole and the buffer space and is discharged to the outside through the exhaust pipe.

According to an embodiment, the exhaust unit may be provided at the bottom of the housing.

According to an embodiment, the apparatus may further include a support unit that supports the substrate in the process space, and the support unit may include a support shaft inserted into the through-hole and the exhaust hole and having a smaller diameter than the through-hole.

According to an embodiment, the exhaust unit may further include a perforated plate provided in the buffer space and having a plurality of perforations formed through the perforated plate, and the perforated plate may surround the support shaft and may be spaced apart from the support shaft.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view illustrating a general plasma processing apparatus;

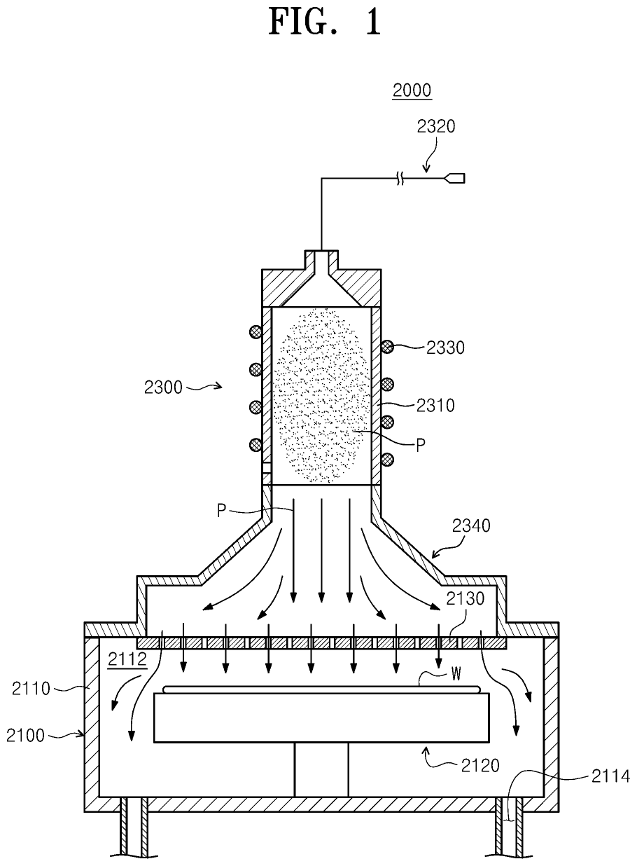

FIG. 2 is a schematic view illustrating substrate treating apparatus of the inventive concept;

FIG. 3 is a view illustrating a substrate treating apparatus provided in a process chamber of FIG. 2;

FIG. 4 is a view illustrating an exhaust unit of FIG. 3;

FIG. 5 is a view illustrating a flow of plasma and/or gas in the substrate treating apparatus of FIG. 3;

FIG. 6 is a view illustrating an exhaust unit according to another embodiment of the inventive concept;

FIG. 7 is a view illustrating an exhaust unit according to another embodiment of the inventive concept; and

FIG. 8 is a view illustrating a substrate treating apparatus according to another embodiment of the inventive concept.

### DETAILED DESCRIPTION

Hereinafter, embodiments of the inventive concept will be described in detail with reference to the accompanying drawings such that those skilled in the art to which the inventive concept pertains can readily carry out the inventive concept. However, the inventive concept may be implemented in various different forms and is not limited to the embodiments described herein. Furthermore, in describing the embodiments of the inventive concept, detailed descriptions related to well-known functions or configurations will be omitted when they may make subject matters of the inventive concept unnecessarily obscure. In addition, components performing similar functions and operations are provided with identical reference numerals throughout the accompanying drawings.

The terms “include” and “comprise” in the specification are “open type” expressions just to say that the corresponding components exist and, unless specifically described to the contrary, do not exclude but may include additional components. Specifically, it should be understood that the terms “include”, “comprise” and “have” when used herein, specify the presence of stated features, integers, steps, operations, components, and/or parts, but do not preclude the presence or addition of one or more other features, integers, steps, operations, components, parts, and/or groups thereof.

The terms of a singular form may include plural forms unless otherwise specified. Furthermore, in the drawings, the shapes and dimensions of components may be exaggerated for clarity of illustration.

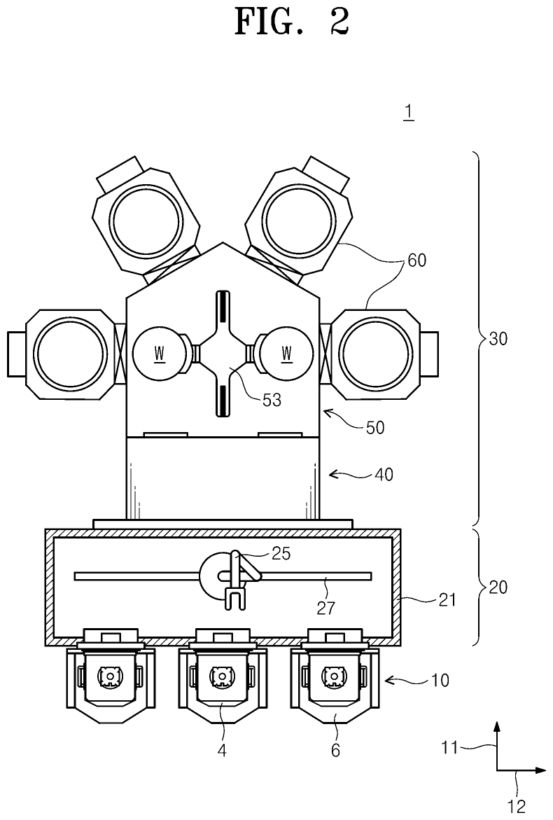

Hereinafter, embodiments of the inventive concept will be described in detail with reference to FIGS. 2 to 7.

FIG. 2 is a schematic view illustrating substrate treating equipment of the inventive concept. Referring to FIG. 2, the substrate treating equipment 1 includes an equipment front end module (EFEM) 20 and a process module 30. The equipment front end module 20 and the process module 30 are arranged in one direction.

The equipment front end module 20 includes a load port 10 and a transfer frame 21. The load port 10 is disposed in the front of the equipment front end module 20 in a first direction 11. The load port 10 includes a plurality of supports 6. The supports 6 are arranged in a row in a second direction 12, and carriers 4 (e.g., cassettes, FOUPs, or the like) in which substrates W to be treated and substrates W completely treated are received are placed on the supports 6. The substrates W to be treated and the substrates W completely treated are received in the carriers 4. The transfer frame 21 is disposed between the load port 10 and the process module 30. The transfer frame 21 includes a first transfer robot 25 that is disposed in the transfer frame 21 and that transfers the substrates W between the load port 10 and the process module 30. The first transfer robot 25 moves along a transfer rail 27 arranged in the second direction 12 and transfers the substrates W between the carriers 4 and the process module 30.

The process module 30 includes a load-lock chamber 40, a transfer chamber 50, and process chambers 60. The transfer module 30 may treat the substrates W transferred from the equipment front end module 20.

The load-lock chamber 40 is disposed adjacent to the transfer frame 21. For example, the load-lock chamber 40 may be disposed between the transfer chamber 50 and the equipment front end module 20. The load-lock chamber 40 provides a space where the substrates W to be treated stand by before transferred to the process chambers 60 or a space where the completely treated substrates W stand by before transferred to the equipment front end module 20.

The transfer chamber 50 may transfer the substrates W. The transfer chamber 50 is disposed adjacent to the load-lock chamber 40. The transfer chamber 50 has a body in a polygonal shape when viewed from above. Referring to FIG. 2, the transfer chamber 50 has a pentagonal body when viewed from above. The load-lock chamber 40 and the plurality of process chambers 60 are disposed around the body. The body has, in sidewalls thereof, passages (not illustrated) through which the substrates W enter or leave the transfer chamber 50, and the passages connect the transfer chamber 50 with the load-lock chamber 40 or the process chambers 60. Doors (not illustrated) are provided for the respective passages to open/close the passages and hermetically seal the interior of the transfer chamber 50. A second transfer robot 53 is disposed in the interior space of the transfer chamber 50 and transfers the substrates W between the load-lock chamber 40 and the process chambers 60. The second transfer robot 53 transfers untreated substrates W standing by in the load-lock chamber 40 to the process chambers 60, or transfers completely treated substrates W to the load-lock chamber 40. Furthermore, the second transfer robot 53 transfers a substrate W between the process chambers 60 to sequentially provide the substrate W to the plurality of process chambers 60. As illustrated in FIG. 2, when the transfer chamber 50 has a pentagonal body, the load-lock chamber 40 is disposed on the sidewall adjacent to the equipment front end module 20, and the process chambers 60 are continuously disposed on the remaining sidewalls. The transfer chamber 50 may be provided in various forms depending on required process modules, in addition to the aforementioned shape.

The process chambers 60 may be disposed adjacent to the transfer chamber 50. The process chambers 60 are disposed around the transfer chamber 50. The plurality of process chambers 60 may be provided. In the process chambers 60, processes may be performed on the substrates W, respectively. The process chambers 60 treat the substrates W transferred from the second transfer robot 53 and provide the completely treated substrates W to the second transfer robot 53. The processes performed in the respective process chambers 60 may differ from one another.

Hereinafter, among the process chambers 60, a substrate treating apparatus 1000 for performing a plasma process will be described in detail.

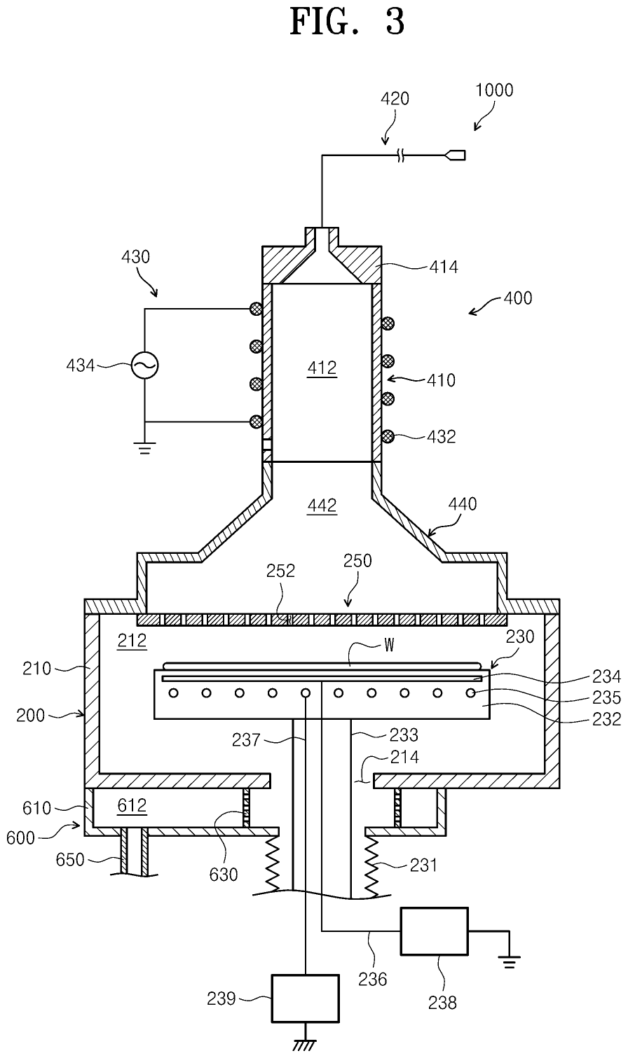

FIG. 3 is a view illustrating the substrate treating apparatus provided in the process chamber of FIG. 2. Referring to FIG. 3, the substrate treating apparatus 1000 performs a predetermined process on a substrate W by using plasma. For example, the substrate treating apparatus 1000 may perform an etching or ashing process on a thin film on the substrate W. The thin film may be various types of films such as a poly silicon film, a silicon oxide film, a silicon nitride film, and the like. Alternatively, the thin film may be a native oxide film or a chemically generated oxide film.

The substrate treating apparatus 1000 may include a process unit 200, a plasma generation unit 400, and an exhaust unit 600.

The process unit 200 provides a space in which the substrate W is placed and subjected to a process. The plasma generation unit 400 generates, outside the process unit 200, plasma from a process gas and supplies the plasma to the process unit 200. The exhaust unit 600 discharges gases staying in the process unit 200 and reaction by-products generated during the substrate treating process to the outside. The exhaust unit 600 maintains the pressure in the process unit 200 at a set pressure.

The process unit 200 may include a housing 210, a support unit 230, and a baffle 250.

The housing 210 may have a process space 212 therein in which the substrate treating process is performed. The housing 210 may be open at the top thereof and may have an opening (not illustrated) that is formed in a sidewall thereof. The substrate W is placed in, or extracted from, the housing 210 through the opening. The opening may be opened or closed by an opening/closing member such as a door (not illustrated). Furthermore, the housing 210 may have an exhaust hole 214 formed in the bottom thereof. The exhaust hole 214 may be formed in the center of the bottom of the housing 210. Plasma P and/or gas introduced into the process space 212 may be discharged to the outside through the exhaust hole 214. Furthermore, the exhaust hole 214 may be used to exhaust the process space 212. The plasma P and/or the gas in the process space 212 may be discharged to the outside through the exhaust hole 214. A support shaft 233 of the support unit 230 that will be described below may be inserted into the exhaust hole 214. The exhaust hole 214 may have a larger diameter than the support shaft 233. When viewed from above, the center of the exhaust hole 214 and the center of the support shaft 233 may coincide with each other. The exhaust hole 214 may connect to a buffer space 612 of the exhaust unit 600 that will be described below.

The support unit 230 supports the substrate W in the process space 212. The support unit 230 may include a support plate 232, the support shaft 233, an electrostatic electrode 234, and a temperature adjustment member 235. The support plate 232 may support the substrate W in the process space 212. The support plate 232 may have a circular plate shape. The support plate 232 may have a seating surface on which the substrate W is seated. For example, the upper surface of the support plate 232 may be a seating surface on which the substrate W is seated. The side of the support plate 232 may be spaced apart from the inner wall of the housing 210. When viewed from above, the support plate 232 may be disposed in the central region of the process space 212. The support plate 232 may be connected with the support shaft 233. The support shaft 233 may be connected with the lower surface of the support plate 232. The support shaft 233 may be inserted into the exhaust hole 214 formed in the bottom of the housing 210. The support shaft 233 may have a smaller diameter than the exhaust hole 214.

The electrostatic electrode 234 may be provided in the support plate 232. The electrostatic electrode 234 may have a plate shape. The electrostatic electrode 234 may be connected with a first power source 238. The first power source 238 may apply power to the electrostatic electrode 234. The electrostatic electrode 234 may generate electrostatic force to clamp the substrate W to the support plate 232. A first interface line 236 connecting the electrostatic electrode 234 and the first power source 238 may be provided in the support shaft 233.

The temperature adjustment member 235 for adjusting the temperature of the support plate 232 may be provided in the support plate 232. The temperature adjustment member 235 may generate cold-heat or warm-heat. The temperature adjustment member 235 may be connected with a second power source 239. The second power source 239 may apply power to the temperature adjustment member 235. The temperature adjustment member 235 may generate cold-heat or warm-heat to adjust the temperature of the support plate 232, thereby adjusting the temperature of the substrate W. A second interface line 237 connecting the temperature adjustment member 235 and the second power source 239 may be provided in the support shaft 233.

The support shaft 233 may move a target object. For example, the support shaft 233 may be connected with the support plate 232 and may move the support plate 232 in an up/down direction. Accordingly, the substrate W seated on the support plate 232 may be moved in the up/down direction. A bellows 231 may surround the support shaft 233. The bellows 231 may surround part of the support shaft 233. The bellows 231 may be formed of a stretchy material. The bellows 231 may prevent the gas in the process space 212 from being released to the outside even though the support shaft 233 is moved in the up/down direction. The bellows 231 may be combined with the exhaust unit 600 that will be described below.

The baffle 250 is located over the support unit 230 to face the support unit 230. The baffle 250 may be disposed between the support unit 230 and the plasma generation unit 400. Plasma generated in the plasma generation unit 400 may pass through a plurality of holes 252 formed in the baffle 250.

The baffle 250 causes the plasma introduced into the process space 212 to be uniformly supplied to the substrate W. The holes 252 formed in the baffle 250 may be provided as through-holes extending from the upper surface of the baffle 250 to the lower surface thereof and may be uniformly formed over the entire area of the baffle 250.

The plasma generation unit 400 may be located over the housing 210 and may generate plasma. The plasma generation unit 400 excites the process gas into plasma and supplies the generated plasma into the process space 212. The plasma generation unit 400 includes a plasma chamber 410, a gas supply unit 420, a power supply unit 430, and a diffusion chamber 440.

The plasma chamber 410 has a plasma generation space 412 formed therein, and the plasma generation space 412 is open at the top and the bottom thereof. The top of the plasma chamber 410 is hermetically sealed from the outside by a gas supply port 414. The gas supply port 414 is connected with the gas supply unit 420. The gas supply unit 420 may supply the process gas into the gas supply port 414. The process gas supplied by the gas supply unit 420 may be delivered to the process space 212 via the plasma generation space 412 and a diffusion space 442.

The power supply unit 430 applies RF power to the plasma generation space 412. The power supply unit 430 includes an antenna 432 and a power source 434.

The antenna 432 is an inductively coupled plasma (ICP) antenna and has a coil shape. The antenna 432 is wound around the plasma chamber 410 a plurality of times. The antenna 432 is wound around the plasma chamber 410 to correspond to the plasma generation space 412. The power source 434 supplies RF power to the antenna 432. The RF power supplied to the antenna 432 is applied to the plasma generation space 412. An induced electric field is formed in the plasma generation space 412 by high-frequency current, and the process gas in the plasma generation space 412 obtains energy required for ionization from the induced electric field and is converted into a plasma state.

The diffusion chamber 440 diffuses the plasma generated in the plasma chamber 410. The diffusion chamber 440 may have the diffusion space 442. The diffusion chamber 440 may have an overall inverted funnel shape and may be open at the top and the bottom thereof. The plasma generated in the plasma chamber 410 may be diffused while passing through the diffusion chamber 440 and may be introduced into the process space 212 through the baffle 250.

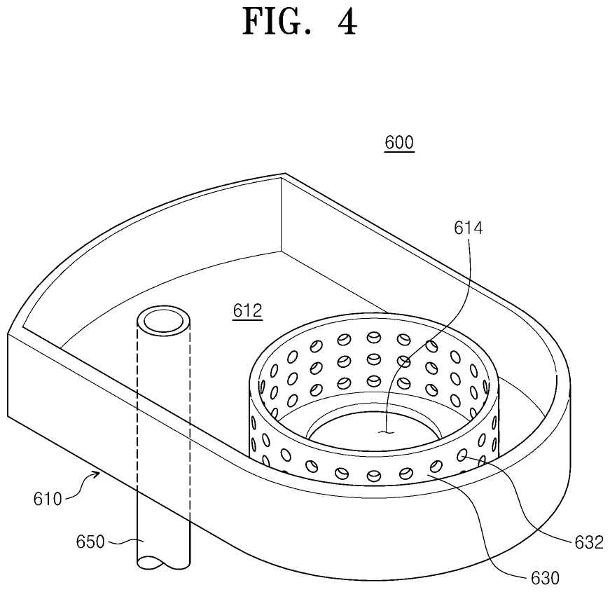

Hereinafter, the exhaust unit 600 according to an embodiment of the inventive concept will be described in detail. The exhaust unit 600 may be provided at the bottom of the housing 210. The exhaust unit 600 may be combined with the bottom of the housing 210. FIG. 4 is a view illustrating the exhaust unit of FIG. 3.

The exhaust unit 600 may discharge the plasma P and/or the process gas in the process space 212 to the outside. The exhaust unit 600 may include a body 610, a perforated plate 630, and an exhaust pipe 650.

The body 610 may have the buffer space 612 therein. The buffer space 612 may connect to the exhaust hole 214 and the process space 212. The plasma P and/or the process gas remaining in the process space 212 may pass through the exhaust hole 214 and the buffer space 612 and may be discharged to the outside through the exhaust pipe 650 that will be described below. The body 610 may be provided at the bottom of the housing 210. The body 610 may be combined with the bottom of the housing 210. The body 610 may have a shape that is open at the top. The body 610 may be combined with the housing 210 to form the buffer space 612. A through-hole 614 may be formed through the body 610. The through-hole 614 may have a larger diameter than the support shaft 233. The support shaft 233 may be inserted into the through-hole 614. When viewed from above, the center of the through-hole 614 and the center of the support shaft 233 may coincide with each other. The bellows 231 described above may be coupled to the lower surface of the body 610.

The body 610 may include an insertion part and a discharge part. The through-hole 614 may be formed through the insertion part of the body 610. The insertion part of the body 610 may have a ring or donut shape. The discharge part of the body 610 may extend from the insertion part in a direction away from the support shaft 233. The exhaust pipe 650 may be connected to the discharge part of the body 610.

The perforated plate 630 may be provided in the buffer space 612. The perforated plate 630 may have a plurality of perforations 632 formed through the perforated plate 630. The perforated plate 630 may have a ring shape when viewed from above. The perforated plate 630 may surround the support shaft 233 and the through-hole 614 when viewed from above. The perforated plate 630 may have a larger diameter than the support shaft 233 and/or the through-hole 614. The perforated plate 630 may surround the support shaft 233 and may be spaced apart from the support shaft 233. The centers of the perforated plate 630, the support shaft 233, and the through-hole 614 may coincide with one another when viewed from above.

The exhaust pipe 650 may be connected with the body 610. The exhaust pipe 650 may be connected with the buffer space 612. The exhaust pipe 650 may be connected to the discharge part of the body 610. The exhaust pipe 650 may have a cylindrical shape. The exhaust pipe 650 may be connected with a pressure-reducing member that provides reduced pressure. For example, the pressure-reducing member may be a pump. Without being limited thereto, however, the pressure-reducing member may be variously modified with well-known machinery and materials capable of providing reduced pressure. When the pressure-reducing member lowers the pressure in the exhaust pipe 650, the plasma P and/or the gas in the process space 212 may pass through the exhaust hole 214 and the buffer space 612 and may be discharged to the outside through the exhaust pipe 650.

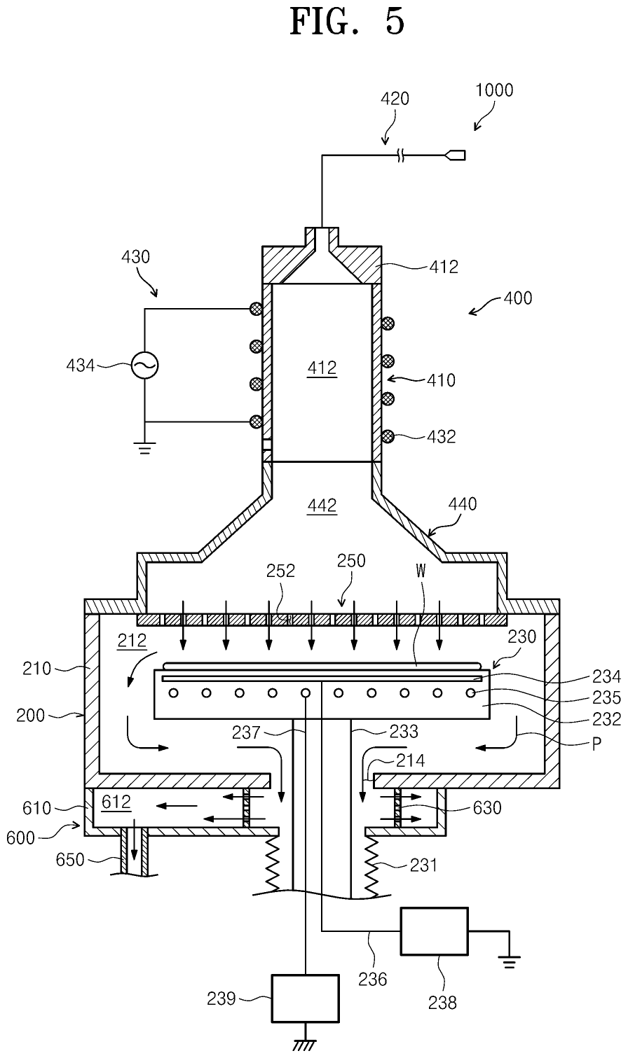

FIG. 5 is a view illustrating a flow of plasma and/or gas in the substrate treating apparatus of FIG. 3. Referring to FIG. 5, plasma P is generated in the plasma chamber 410. Specifically, the gas supply unit 420 supplies the process gas into the plasma generation space 412 of the plasma chamber 410, and the power supply unit 430 forms an RF electromagnetic field. The process gas supplied by the gas supply unit 420 is excited into a plasma state by the RF electromagnetic field.

The plasma P and the process gas may be supplied into the process space 212 via the plasma generation space 412 and the diffusion space 442. The plasma P and the process gas supplied into the process space 212 may be delivered to the substrate W.

The plasma P and/or the process gas in the process space 212 may be discharged to the outside through the exhaust hole 214. The plasma P and/or the process gas introduced into the exhaust hole 214 may be discharged to the outside through the exhaust unit 600. The plasma P and/or the process gas introduced into the exhaust hole 214 may be discharged to the outside through the buffer space 612 and the exhaust pipe 650. In a general substrate treating apparatus, exhaust ports for evacuating a process chamber are connected to the edge region of the bottom of the process chamber. However, in this case, the efficiency in treating a substrate W may be deteriorated because plasma and/or a process gas flows toward the edge region in the process chamber. Accordingly, a way of connecting the exhaust ports to the central region of the bottom of the process chamber may be taken into consideration, but the way is not easy due to interference between the exhaust ports and a support shaft. In contrast, according to an embodiment of the inventive concept, the exhaust unit 600 is provided at the bottom of the housing 210 and forms the buffer space 612. The plasma P and/or the process gas in the process space 212 is discharged to the outside through the exhaust pipe 650 connected to the buffer space 612. The exhaust unit 600 of the inventive concept enables a completely symmetric arrangement of the machinery in the process space 212, thereby achieving a uniform flow of the plasma P and/or the process gas. Furthermore, the clearance between the support shaft 233 and the exhaust hole 214 remains constant around the support shaft 233 when viewed from above. That is, deterioration in the efficiency in treating the substrate W may be minimized because the plasma P and/or the process gas in the process space 212 is discharged through the central region of the process space 212. Moreover, the exhaust pipe 650 is connected with the buffer space 612, and thus a space limitation in the arrangement of the exhaust pipe 650 may be minimized. In addition, the perforated plate 630 is provided in the buffer space 612 and surrounds the support shaft 233 when viewed from above, and the center of the perforated plate 630 coincides with the center of the support shaft 233. That is, the perforated plate 630 may alleviate a non-uniform flow of the plasma P and/or the process gas that may occur when the exhaust pipe 650 is connected to the edge of the buffer space 612.

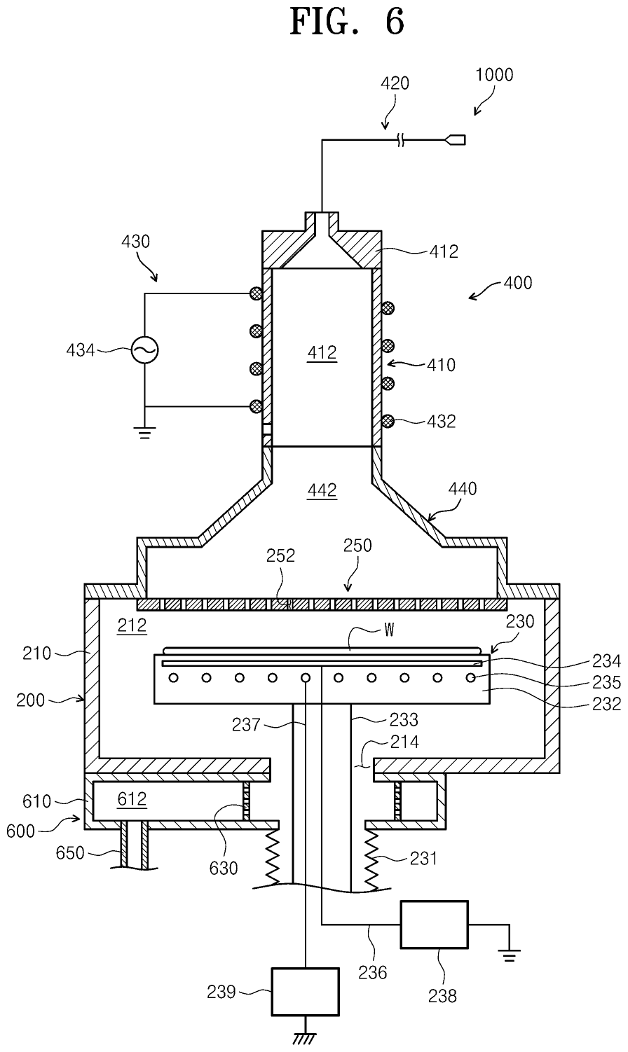

In the above-described embodiment, it has been exemplified that the body 610 is open at the top thereof and is combined with the housing 210 to form the buffer space 612. However, the body 610 is not limited thereto. For example, as illustrated in FIG. 6, a blocking plate may be provided at the top of the body 610.

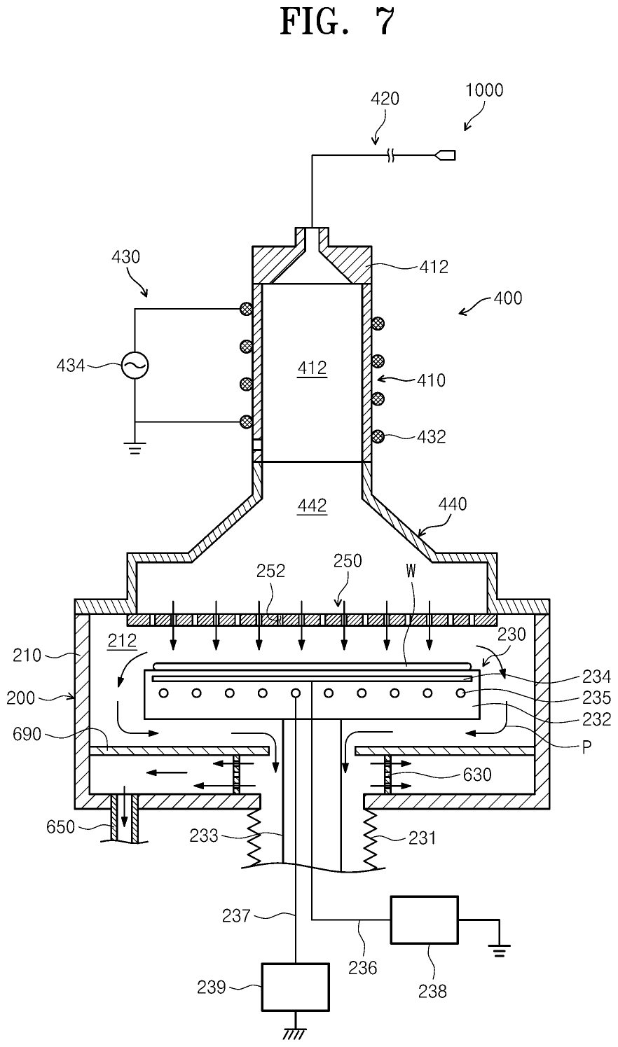

In the above-described embodiment, it has been exemplified that the exhaust unit 600 is provided at the bottom of the housing 210. However, the exhaust unit 600 is not limited thereto. FIG. 7 is a view illustrating an exhaust unit according to another embodiment of the inventive concept. Referring to FIG. 7, the exhaust unit may include a buffer plate 690. The buffer plate 690 may be provided in a buffer space 212. The buffer plate 690 may have an opening formed therein. A support shaft 233 may be inserted into the opening of the buffer plate 690. The opening of the buffer plate 690 may have a larger diameter than the support shaft 233. The buffer plate 690 may be combined with the inner wall of a housing 210 to form a buffer space. Accordingly, plasma P and/or a process gas introduced into the process space 212 may flow into the buffer space through the opening. The plasma P and/or the process gas introduced into the buffer space may be discharged to the outside through an exhaust pipe 650 connected to the edge region of the bottom of the housing 210. A perforated plate 630 has a configuration and/or an effect that is the same as, or similar to, that of the perforated plate 630 described above. Therefore, detailed description thereabout will be omitted.

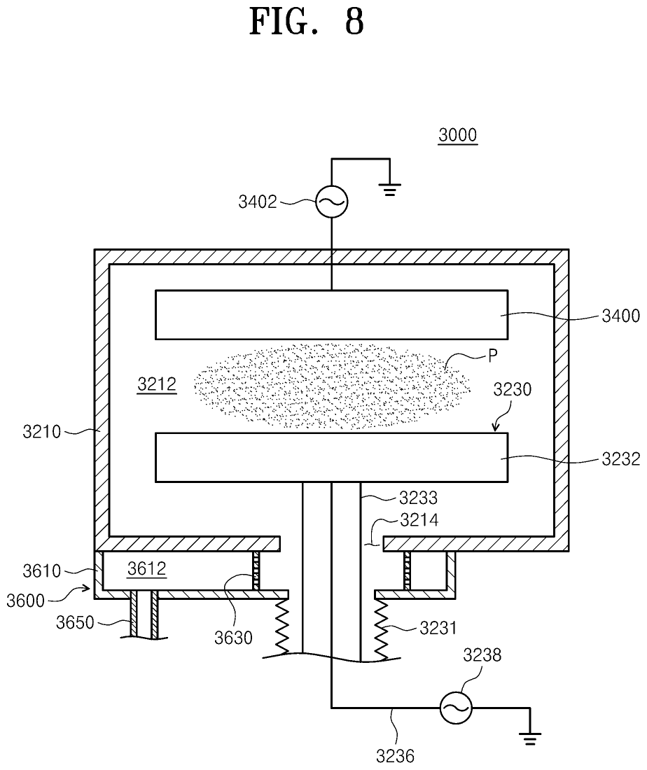

In the above-described embodiment, it has been exemplified that the substrate treating apparatus 1000 is a plasma processing apparatus of an inductively coupled plasma (ICP) type. However, the inventive concept is not limited thereto. The exhaust unit 600 described above may be identically or similarly applied to a plasma processing apparatus of a capacitively coupled plasma (CCP) type. For example, referring to FIG. 8, a substrate treating apparatus 3000 may treat a substrate by generating plasma. The substrate treating apparatus 3000 may be a plasma processing apparatus of a CCP type. The substrate treating apparatus 3000 may include a housing 3210, a support unit 3230, an upper electrode 3400, and an exhaust unit 3600.

The housing 3210 may have a process space 3212 therein. The housing 3210 may have an exhaust hole 3214 formed through the housing 3210. The exhaust hole 3214 may be formed in the bottom of the housing 3210. The exhaust hole 3214 may be formed in the central region of the bottom of the housing 3210.

The support unit 3230 may support the substrate in the process space 3212. The support unit 3230 may include a bellows 3231, a support plate 3232, a support shaft 3233, an RF power source 3238, and a power line 3236. A lower electrode may be provided in the support plate 3232. The lower electrode provided in the support plate 3232 may face the upper electrode 3400 that will be described below. The lower electrode and the upper electrode 3400 facing each other may generate plasma P in the space therebetween. The lower electrode may be connected with the RF power source 3238. The RF power source 3238 may apply RF power to the lower electrode. The power line 3236 connecting the RF power source 3238 and the lower electrode may be provided in the support shaft 3233. The other components, such as the bellows 3231 and the support shaft 3233, which are included in the support unit 3230 are the same as, or similar to, those of the support unit 230 described above. Therefore, detailed descriptions thereabout will be omitted.

The upper electrode 3400 may be disposed in a higher position than the support unit 3230. The upper electrode 3400 may be provided in the process space 3212. The upper electrode 3400 may face the lower electrode described above and may generate the plasma P together with the lower electrode. The upper electrode 3400 may be connected with an upper power source 3402.

The exhaust unit 3600 may be provided at the bottom of the housing 3210. The exhaust unit 3600 has a configuration that is the same as, or similar to, the configuration of the exhaust unit 600 described above. Therefore, detailed description thereabout will be omitted.

The apparatuses that treat a substrate with plasma have been exemplified in the above-described embodiments. However, the inventive concept may be identically or similarly applied to various apparatuses for discharging gas in a process chamber.

According to the embodiments of the inventive concept, the substrate treating apparatuses may efficiently treat a substrate.

According to the embodiments of the inventive concept, the substrate treating apparatuses may increase the uniformity of substrate treatment by allowing plasma and/or gas to uniformly flow in the interior space of the housing.

According to the embodiments of the inventive concept, the substrate treating apparatuses may uniformly perform substrate treatment by allowing plasma and/or gas to uniformly flow in the interior space of the housing.

According to the embodiments of the inventive concept, the substrate treating apparatuses may minimize a space limitation in the arrangement of the exhaust pipe due to the support shaft.

Effects of the inventive concept are not limited to the aforementioned effects, and any other effects not mentioned herein may be clearly understood from this specification and the accompanying drawings by those skilled in the art to which the inventive concept pertains.

The above description exemplifies the inventive concept. Furthermore, the above-mentioned contents describe the exemplary embodiments of the inventive concept, and the inventive concept may be used in various other combinations, changes, and environments. That is, variations or modifications can be made to the inventive concept without departing from the scope of the inventive concept that is disclosed in the specification, the equivalent scope to the written disclosures, and/or the technical or knowledge range of those skilled in the art. The written embodiments describe the best state for implementing the technical spirit of the inventive concept, and various changes required in specific applications and purposes of the inventive concept can be made. Accordingly, the detailed description of the inventive concept is not intended to restrict the inventive concept in the disclosed embodiment state. In addition, it should be construed that the attached claims include other embodiments.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. An apparatus for treating a substrate, the apparatus comprising:
a housing having a process space inside and having an exhaust hole formed through the housing;
a support unit configured to support the substrate in the process space; and
an exhaust unit provided at the bottom of the housing and configured to exhaust the process space,
wherein the exhaust unit includes:
a body having a buffer space inside and having a through-hole formed through the body, the buffer space connecting to the process space; and
an exhaust pipe configured to discharge gas in the buffer space, and
wherein the support unit includes:
a support plate configured to support the substrate in the process space; and
a support shaft connected with the support plate and inserted into the through-hole and the exhaust hole, the support shaft having a smaller diameter than the through-hole.

2. The apparatus of claim 1, wherein the exhaust unit further includes a perforated plate provided in the buffer space and having a plurality of perforations formed through the perforated plate, and
wherein the perforated plate surrounds the support shaft and is spaced apart from the support shaft.

3. The apparatus of claim 1, wherein the exhaust pipe is connected to an edge of the buffer space when viewed from above.

4. The apparatus of claim 3, wherein the body includes:
an insertion part having a ring shape through which the through-hole is formed; and
a discharge part extending from the insertion part in a direction away from the support shaft, and
wherein the exhaust pipe is connected to the discharge part.

5. The apparatus of claim 1, wherein a blocking plate is provided at the top of the body.

6. The apparatus of claim 1, wherein the body is combined with the housing to form the buffer space.

7. The apparatus of claim 1, wherein the center of the support shaft and the center of the through-hole coincide with each other when viewed from above.

8. The apparatus of claim 1, wherein the support shaft is provided so as to be movable in an up/down direction; and
wherein the apparatus further comprises a bellows configured to surround the support shaft and coupled with the body.

9. The apparatus of claim 1, further comprising:
a gas supply unit located over the support unit and configured to supply the gas into the process space.

10. The apparatus of claim 1, further comprising:
a power supply unit located over the support unit and configured to generate plasma from the gas.

11. The apparatus of claim 1, wherein the support plate has a circular plate shape, and a side of the support plate is spaced apart from an inner wall of the housing.

12. The apparatus of claim 1, wherein the exhaust hole is formed in the center of the bottom of the housing.

13. The apparatus of claim 1, wherein the support plate is connected with a power source and generates electrostatic force, and
wherein an interface line connecting the power source and the support plate is provided in the support shaft.

14. The apparatus of claim 1, wherein a temperature adjustment member configured to adjust temperature of the support plate is provided in the support plate, and
wherein an interface line connecting the temperature adjustment member and a power source is provided in the support shaft.

15. The apparatus of claim 1, wherein a lower electrode is provided in the support plate,
wherein the lower electrode is connected with an RF power source configured to supply RF power to the lower electrode, and
wherein a power line connecting the lower electrode and the RF power source is provided in the support shaft.

16. An apparatus for treating a substrate, the apparatus comprising:
an equipment front end module having a load port on which a carrier having the substrate received therein is seated; and
a process module configured to treat the substrate transferred from the equipment front end module,
wherein the process module includes:
a transfer chamber configured to transfer the substrate; and
a process chamber disposed adjacent to the transfer chamber and configured to treat the substrate,
wherein the process chamber includes:
a housing having a process space inside and having an exhaust hole formed through the housing;
a support unit configured to support the substrate in the process space;
a gas supply unit located over the support unit and configured to supply gas into the process space;
a plasma generation unit located over the support unit and configured to generate plasma from the gas; and
an exhaust unit provided at the bottom of the housing and configured to exhaust the process space,
wherein the exhaust unit includes:
a body having a buffer space inside and having a through-hole formed through the body, the buffer space connecting to the process space; and
an exhaust pipe configured to discharge the gas in the buffer space, and
wherein the support unit includes:
a support plate configured to support the substrate in the process space; and
a support shaft connected with the support plate and inserted into the through-hole and the exhaust hole, the support shaft having a smaller diameter than the through-hole.

17. The apparatus of claim 16, wherein the exhaust unit further includes a perforated plate provided in the buffer space and having a plurality of perforations formed through the perforated plate, and
wherein the perforated plate surrounds the support shaft and is spaced apart from the support shaft.

18. The apparatus of claim 16, wherein the body includes:
an insertion part having a ring shape through which the through-hole is formed; and
a discharge part extending from the insertion part in a direction away from the support shaft, and
wherein the exhaust pipe is connected to the discharge part.

19. An apparatus for treating a substrate, the apparatus comprising:
a housing having a process space inside and having an exhaust hole formed through the housing; and
an exhaust unit configured to exhaust the process space,
wherein the exhaust unit includes:
a body having a buffer space inside and having a through-hole formed through the body; and
an exhaust pipe connected with the buffer space, and
wherein gas in the process space passes through the exhaust hole and the buffer space and is discharged to the outside through the exhaust pipe.

20. The apparatus of claim 19, wherein the exhaust unit is provided at the bottom of the housing.

21. The apparatus of claim 19, wherein the apparatus further comprises a support unit configured to support the substrate in the process space, and
wherein the support unit includes a support shaft inserted into the through-hole and the exhaust hole and having a smaller diameter than the through-hole.

22. The apparatus of claim 21, wherein the exhaust unit further includes a perforated plate provided in the buffer space and having a plurality of perforations formed through the perforated plate, and
wherein the perforated plate surrounds the support shaft and is spaced apart from the support shaft.
